(19) United States
(12) Patent Application Publication
(10) Pub. No.: US 2005/0214651 A1
(43) Pub. Date: Sep. 29, 2005

(54) APERTURE PLATE FOR OPTICAL LITHOGRAPHY SYSTEMS

(76) Inventor: Yuan-Hsun WU, Tao-Yuan Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/708,780

(22) Filed: Mar. 25, 2004

(51) Int. Cl. G03F 9/00

(52) U.S. Cl. 430/4

(57) ABSTRACT

A pupil aperture plate situated on a light path of an optical lithography system for providing specific illumination patterns is disclosed. The pupil aperture plate includes a plate body having thereon a pole aperture (defined by σᵢₙₙₑᵣ) located at the center of the plate. A set of four sector apertures, each of which has an opening angle θ, radiating from a reference center point of the pole aperture. The distance of the sector aperture from the reference center point of the pole aperture is defined by σₒᵤₜₑᵣ. The pupil aperture plate provides Bow-Pole and Quasar illumination patterns in combination with conventional and annular illuminations, respectively.

### BACKGROUND OF INVENTION

1. Field of the Invention

The present invention relates to an optical device installed in an optical lithographic system, and more particularly, to a specifically designed aperture plate, which when in combination with conventional light and annual light can provide Bow-Pole and Quasar illumination for optical lithographic system.

2. Description of the Prior Art

The dramatic increase in performance and cost reduction in the electronics industry are attributable to innovations in the integrated circuit and packaging fabrication processes. The speed and performance of the chips is dictated by the lithographic minimum printable size. Lithography, which replicates a pattern rapidly from chip to chip or wafer to wafer, also determines the throughput and the cost of electronic systems. A lithographic system includes exposure tool, mask, resist, and all of the processing steps to accomplish pattern transfer from a mask to a resist and then to devices.

In optical projection lithography, resolution is expressed by the well-known Rayleigh equation:
R=k₁λ/NA,
where λ and NA are the exposure wavelength and numerical aperture of the optical lithography tool, and k₁ is a constant (usually between 0.4˜1) for a specific lithographic process.

As the wavelength becomes shorter, the light source filtered for G- (436 nm) and H-lines, and later for the I-line (365 nm) becomes more complex and expensive. Initially, the light source was a mercury lamp. Lithography at a wavelength of 248 nm spurred the development of a reliable and line narrowed KrF laser.

Off-axis illumination techniques such as quadrupole and annular illumination have been proposed to enlarge the depth-of-focus. A depth-of-focus enhancement effect in these off-axis illumination techniques is achieved with using an off-axis filter (or aperture plate) mounted on the fly's eye lens. The filter has a small aperture to select an effective light flux for depth-of-focus enhancement for the target geometry or the orientation of the image.

In the manufacturing of high-density semiconductor memory device such as high-density DRAMs, 90-degree quadrupole off-axis illumination is used to improve critical dimension (CD) and Normalized Image Log-Slope (NILS) of memory array patterns. As known in the art, NILS is correlated with image quality and process window. The higher the NILS is, the larger the process window can be obtained. On the other hand, in the case when manufacturing contact devices, to improve the process window of contact hole and iso-dense contact bias, another type of illumination such as Bow-Pole aperture is needed. It is costly for the chipmakers to prepare two types of aperture plates in hand.

### SUMMARY OF INVENTION

Accordingly, it is the primary object of the present invention to provide an aperture plate for optical lithographic systems, which when in combination with conventional light and annual light can provide Bow-Pole and Quasar illumination.

According to the claimed invention, an aperture plate for optical lithographic systems is provided. The aperture plate comprises an opaque plate having thereon a central pole aperture; and a set of four sector apertures having substantially the same opening angel θ. The sector apertures radiating from a center point of the pole aperture communicate with the central pole aperture. The aperture plate when in combination with conventional light and an annular light can provide Bow-Pole and Quasar illumination.

Other objects, advantages and novel features of the invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a plan view of an aperture plate in accordance with the first preferred embodiment of the present invention;

FIG. 2 illustrates the application when the aperture plate of FIG. 1 incorporates with a conventional light source in accordance with the present invention;

FIG. 3 illustrates the application when the aperture plate of FIG. 1 incorporates with an annual light source in accordance with the present invention;

FIG. 4 is a plan view of an aperture plate in accordance with the second preferred embodiment of the present invention;

FIG. 5 illustrates the application when the aperture plate of FIG. 4 incorporates with a conventional light source in accordance with the present invention; and

FIG. 6 illustrates the application when the aperture plate of FIG. 4 incorporates with an annual light source in accordance with the present invention.

### DETAILED DESCRIPTION

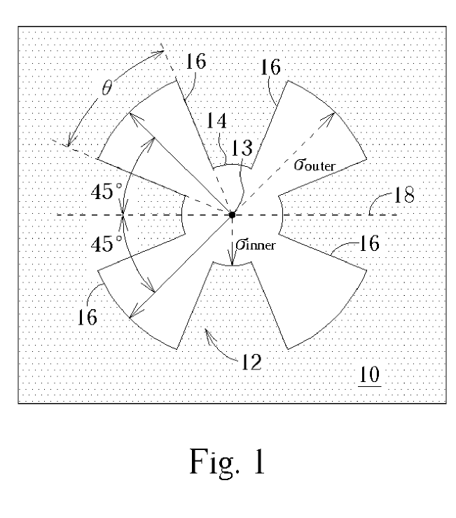

Please refer to FIG. 1. FIG. 1 is a plan view of an aperture plate 10 in accordance with the first preferred embodiment of the present invention. As shown in FIG. 1, the aperture plate 10 comprises a specifically designed aperture pattern 12. The aperture pattern 12 includes a central circular opening (pole aperture) 14 and a set of four sector openings 16 with the same opening angle θ. A horizontal reference line 18 intersecting the center point 13 of the central circular opening 14 is defined on the plate plan. As specifically indicated, each central radiating line of the four sector openings 16 is rotated 45 degree (45°) with respect to the horizontal reference line 18, such that the four sector openings 16 represent a 45° rotation status.

According to the first preferred embodiment of this invention, the size and dimension of the central circular opening 14 is determined by radius σᵢₙₙₑᵣ value, which is preferably 0.35, but not limited thereto. It is to be understood that the magnitude of σᵢₙₙₑᵣ value depends upon real operation conditions and process requirements. According to the first preferred embodiment of this invention, each of the four sector openings 16 radiating from the center point of the central circular opening 14 has an opening angle θ of about 35°, but not limited thereto. Another parameter for determining the dimension of the four sector openings 16 is radius σₒᵤₜₑᵣ value.

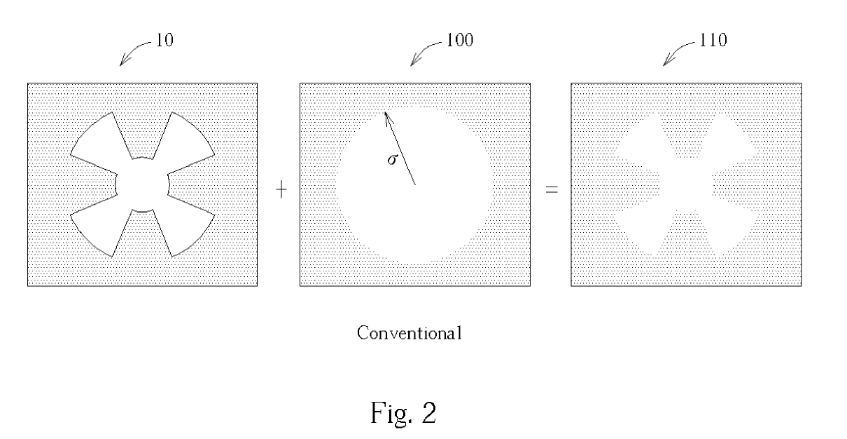

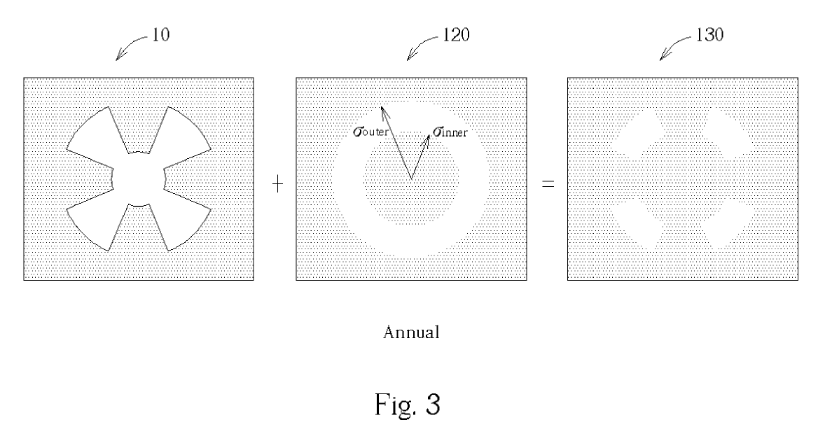

Please refer to FIG. 2 and FIG. 3. FIG. 2 illustrates the application when the aperture plate 10 incorporates with conventional light source. FIG. 3 illustrates the application when the aperture plate 10 incorporates with annual light source. As shown in FIG. 2, in accordance with the present invention, the aperture plate 10 when in combination with the conventional light source 100 with a fixed sigma value σ, a Bow-Pole illumination 110 is obtained. The Bow-Pole illumination 110 is preferably used to improve the process window of contact hole and iso-dense contact bias.

As shown in FIG. 3, in accordance with the present invention, the aperture plate 10 when in combination with the annual light source 120 defined with a fixed inner sigma value σᵢₙₙₑᵣ and outer sigma value σₒᵤₜₑᵣ, a Quasar (45-degree rotated) illumination 130 is obtained. The resultant Quasar illumination 130 is preferably used to improve critical dimension (CD) and Normalized Image Log-Slope (NILS) of memory array patterns.

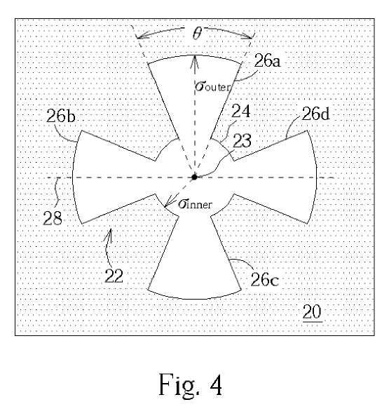

Please refer to FIG. 4. FIG. 4 is a plan view of an aperture plate 20 in accordance with the first preferred embodiment of the present invention. As shown in FIG. 4, likewise, the aperture plate 20 comprises a specifically designed aperture pattern 22. The aperture pattern 22 includes a central circular opening 24 and a set of four sector openings 26a, 26b, 26c, and 26d with the same opening angle θ. A horizontal reference line 28 intersecting the center point 23 of the central circular opening 24 is defined on the plate plan. Each central radiating line of the sector openings 26a and 26c is normal to the horizontal reference line 28 (Only central radiating line of the sector openings 26a is shown), while each central radiating line of the sector openings 26b and 26d is parallel with the horizontal reference line 28.

According to the second preferred embodiment of this invention, the size and dimension of the central circular opening 24 is also determined by radius σᵢₙₙₑᵣ value, which is preferably 0.35, but not limited thereto. It is to be understood that the magnitude of σᵢₙₙₑᵣ value depends upon real operation conditions and process requirements. According to the second preferred embodiment of this invention, each of the four sector openings 26a, 26b, 26c, and 26d radiating from the center point of the central circular opening 24 has an opening angle θ of about 35°, but not limited thereto. Another parameter for determining the dimension of the four sector openings 26a, 26b, 26c, and 26d is radius σₒᵤₜₑᵣ value.

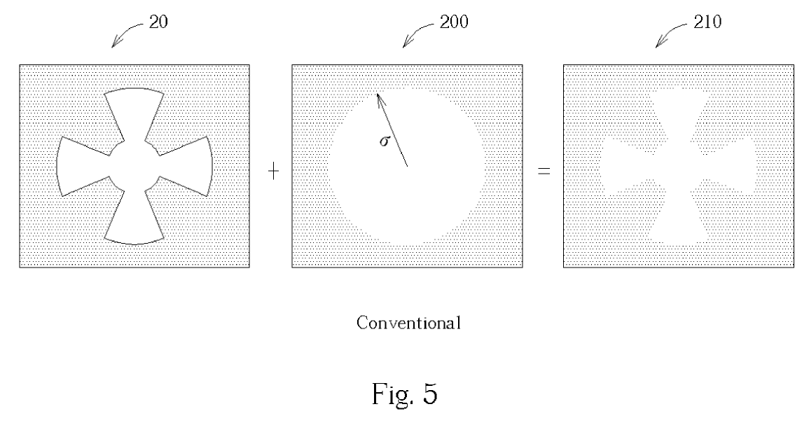

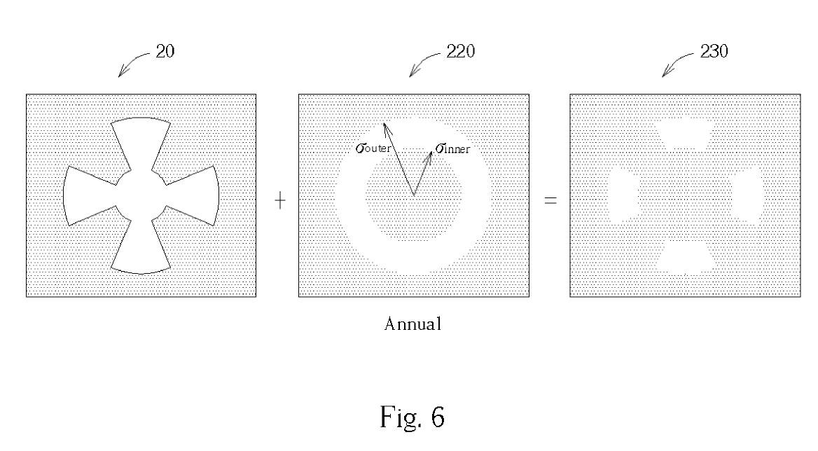

Please refer to FIG. 5 and FIG. 6. FIG. 5 illustrates the application when the aperture plate 20 incorporates with conventional light source. FIG. 6 illustrates the application when the aperture plate 20 incorporates with annual light source. As shown in FIG. 5, in accordance with the present invention, the aperture plate 20 when in combination with the conventional light source 200 with a fixed sigma value σ, a Bow-Pole (90 degree) illumination 210 is obtained. The Bow-Pole (90 degree) illumination 210 is preferably used to improve the process window of contact hole and iso-dense contact bias.

As shown in FIG. 6, in accordance with the present invention, the aperture plate 20 when in combination with the annual light source 220 defined with a fixed inner sigma value σᵢₙₙₑᵣ and outer sigma value σₒᵤₜₑᵣ, a Quasar (90-degree) illumination 230 is obtained. The resultant Quasar illumination 230 is preferably used to improve critical dimension (CD) and Normalized Image Log-Slope (NILS) of memory array patterns.

Those skilled in the art will readily observe that numerous modification and alterations of the present invention may be made while retaining the teachings of the invention. Accordingly, the above disclosure should be construed as limited only by the metes and bounds of the appended claims.

1. An aperture plate for optical lithographic systems, comprising:
an opaque plate having thereon a central pole aperture; and
a set of four sector apertures having substantially the same opening angel θ, wherein said sector apertures radiating from a center point of said pole aperture communicate with said central pole aperture; wherein said aperture plate when in combination with conventional light and an annular light can provide Bow-Pole and Quasar illumination.

2. The aperture plate for optical lithographic systems according to claim 1 wherein dimension of said central pole aperture is determined by a sigma σᵢₙₙₑᵣ value.

3. The aperture plate for optical lithographic systems according to claim 1 wherein dimension of each of said sector apertures is determined by a sigma σₒᵤₜₑᵣ value.

4. The aperture plate for optical lithographic systems according to claim 1 wherein said opening angel θ is about 35°.
